(19) United States
(12) Patent Application Publication
(10) Pub. No.: US 2011/0076795 A1
(43) Pub. Date: Mar. 31, 2011

(54) MIXTURES OF ORGANOPOLYSILOXANE COPOLYMERS

(75) Inventors: Oliver Schaefer, Burghausen (DE); Ernst Selbertinger, Burghausen (DE)

(73) Assignee: WACKER CHEMIE AG, Munich (DE)

(21) Appl. No.: 12/993,882

(22) PCT Filed: May 25, 2009
(86) PCT No.: PCT/EP2009/056299

§ 371 Date: Nov. 22, 2010

(30) Foreign Application Priority Data
May 29, 2008 (DE) 10 2008 002 075.3

(51) Int. Cl. H01L 31/18; C08L 83/10; C08K 5/3475; C08K 5/3492

(52) U.S. Cl. 438/66; 524/500; 524/91; 524/100; 257/E31.001

(57) ABSTRACT

Organopolysiloxane/polyuria/polyurethane block copolymers containing a compatible UV stabilizer are transparent and resistant to degradation.

The invention relates to transparent mixtures, containing organopolysiloxane copolymers and their use.

The properties of organic thermoplastics and silicone elastomers are complementary within wide ranges. Organic thermoplastics have excellent mechanical strength and elasticity and can easily be processed from the melt by extrusion. On the other hand, silicone elastomers have excellent transparency and also heat, UV and weathering resistance. They retain their elastic properties at relatively low temperatures and therefore do not tend to become brittle. In addition, they have specific water-repellent and antiadhesive surface properties.

Conventional polysiloxanes are employed for elastomers, seals, adhesives and sealants or any antiadhesive coatings in the form of thixotropic pastes. To achieve the desired final strengths, different ways of curing the compositions have been developed, with the objective of solidifying the desired structures and setting the mechanical properties. However, the polymers usually have to be blended by addition of reinforcing additives such as pyrogenic silicas in order to achieve satisfactory mechanical properties; this usually occurs at the expense of the transparency. Among curing systems, a distinction is made essentially between high-temperature vulcanizing systems (HTV) and room-temperature vulcanizing systems (RTV). In the case of RTV compositions, there are both one-component (1K) and two-component (2K) systems. In the case of the 2K systems, the two components are mixed and thus catalytically activated and cured. The curing mechanism and the catalyst required can be different in these systems. Curing is usually effected by peroxidic crosslinking, by hydrosilylation by means of platinum catalysis or, for example, via condensation reactions. Although such 2K systems have very long pot lives, the mixing ratios of the two components have to be adhered to precisely in order to achieve optimal properties, which leads to an increased outlay in terms of apparatus in processing.

1K systems likewise cure by means of peroxidic crosslinking, by hydrosilylation by means of platinum catalysis or, for example, via condensation reactions. However, either an additional processing step is necessary here to incorporate the crosslinking catalyst or the compositions have only a limited pot life. However, in all these systems, the products are insoluble after processing and, for example, can also no longer be recycled.

The combination of segments of thermoplastic elastomers and the silicone polymers should therefore make it possible to obtain materials which have good mechanical properties and at the same time display greatly simplified processing opportunities compared to the silicones but continue to have the positive properties of the silicones. Combining the advantages of the two systems can therefore lead to compounds having low glass transition temperatures, low surface energies, especially improved transparency, low water absorption and physiological inertness.

Examples of such materials are known from EP 0250248, EP 822951, WO 07075317, which are essentially based on the incorporation of diaminosiloxanes into organic polymers. These polymers in fact display good thermoplastic processing and good transparency. However, these polymers systems have the disadvantage of the still partly unsatisfactory resistance to UV light, particularly in the range <350 nm, which is caused by introduction of organic components into the inorganic silicone. However, these organic components are also responsible for yellowing phenomena which are observed in the case of these polymers, depending on storage conditions.

In addition, there is the problem, especially in the case of materials having relatively low molecular weights, that the end groups can likewise lead, by oxidative degradation processes, to clouding or yellowing of the materials.

However, since these high-transparency properties are of interest in various applications, especially in the exterior sector, it would therefore be desirable to have ways of obtaining light-stable, colorless, transparent compositions.

The use of stabilizers in silicone-organic copolymers is mentioned in WO2007/079028 for structurally similar compounds.

However, it has been found that the general use of, for example, light stabilizers is not a suitable way of producing highly transparent stabilized systems since the stabilizers generally used display only unsatisfactory miscibility with the silicone copolymers and thus lead to severe clouding as a result of demixing.

It is an object of the invention to improve the prior art, in particular to provide polymers which are transparent and have thermal and optical stability.

It has surprisingly been found that there are organic stabilizers which have such compatibility with the claimed copolymers that the resulting copolymer/stabilizer mixtures have the desired thermal and optical stability but still display an extremely high transparency.

In addition, the polymer has to be structurally altered, especially in the case of polymers having relatively low molecular weights, by introduction of further additives or by the targeted influencing of the chemical basis in such a way that there is per se only a very small tendency for even the unstabilized material to yellow. This is preferably achieved by targeted derivatization of the chain ends.

The invention provides compositions containing from 50 to 99.999% of an organopolysiloxane-polyurea-polyurethane block copolymer of the general formula (1)

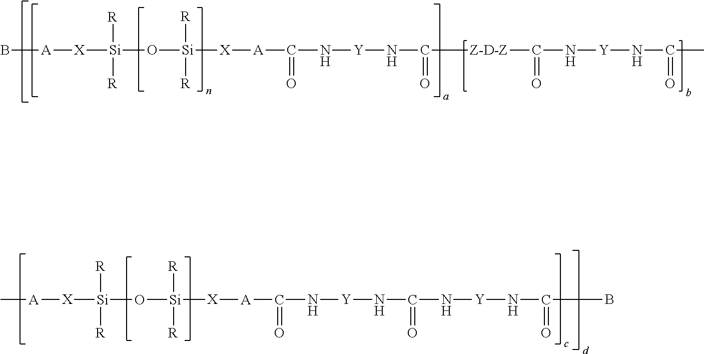

and containing from 0.001% to 10% of a UV absorber which are compatible with the polymer of the general formula I,

where
R is a monovalent hydrocarbon radical which has from 1 to 20 carbon atoms and is optionally substituted by fluorine or chlorine,
X is an alkylene radical which has from 1 to 20 carbon atoms and in which nonadjacent methylene units can be replaced by —O— groups,
A is an oxygen atom or an amino group —NR′—,
Z is an oxygen atom or an amino group —NR′—,
R′ is hydrogen or an alkyl radical having from 1 to 10 carbon atoms,
Y is a divalent hydrocarbon radical which has from 1 to 20 carbon atoms and is optionally substituted by fluorine or chlorine,
D is an alkylene radical which has from 1 to 700 carbon atoms and is optionally substituted by fluorine, chlorine, C₁-C₆-alkyl or C₁-C₆-alkyl ester and in which nonadjacent methylene units can be replaced by —O—, —COO—, —OCO— or —OCOO— groups,
B is hydrogen or a functional or nonfunctional organic or organosilicon radical,
n is from 1 to 1000,
a is at least 1,
b is from 0 to 40,
c is from 0 to 30 and
d is greater than 0.

R is preferably a monovalent, in particular unsubstituted, hydrocarbon radical having from 1 to 6 carbon atoms. Particularly preferred radicals R are methyl, ethyl, vinyl and phenyl.

X is preferably an alkylene radical having from 1 to 10 carbon atoms. The alkylene radical X is preferably not interrupted.

A is preferably an NH group.

Z is preferably an oxygen atom or an NH group.

Y is preferably a hydrocarbon radical which has from 3 to 14 carbon atoms and is preferably unsubstituted. Y is preferably an aralkylene radical or a linear or cyclic alkylene radical. Y is very particularly preferably a saturated alkylene radical.

D is preferably an alkylene radical having at least 2, in particular at least 4, carbon atoms and not more than 12 carbon atoms.

Preference is likewise given to D being a polyoxyalkylene radical, in particular a polyoxyethylene radical or polyoxypropylene radical having at least 20, in particular at least 100, carbon atoms and not more than 800, in particular not more than 200, carbon atoms.

The radical D is preferably unsubstituted.

n is preferably at least 3, in particular at least 25, and preferably not more than 140, in particular not more than 100, particularly preferably not more than 60.

a is preferably not more than 50.

When b is not 0, b is preferably not more than 50, in particular not more than 25.

c is preferably not more than 10, in particular not more than 5.

Preference is given to stabilizers or stabilizer mixtures which have a viscosity at 20° C. of less than 10 k Pas, particularly preferably a viscosity of less than 1000 Pas, very particularly preferably a viscosity of less than 100 Pas, i.e. are liquid at RT. In contrast to organic polymers, solid pulverulent stabilizers do not dissolve in the organopolysiloxane-polyurea-polyurethane block copolymers and thus lead to scattering sites which reduce the transparency.

When the UV absorbers of the invention are used in the wavelength range from 400 nm to 430 nm, the transmission at a layer thickness of 0.5 mm is preferably greater than 85%.

Preference is likewise given, when the UV absorbers of the invention are used, to the absorption at a layer thickness of 0.55 mm and a wavelength of 350 nm being >80%.

Examples of UV absorbers are preferably 4-hydroxybenzoates, benzophenones such as 2-hydroxybenzophenones, benzotriazoles such as preferably 2-hydroxyphenylbenzotriazoles or triazine compounds.

Examples of UV absorbers.

| | |
|---|---|
| 2-Hydroxybenzophenones | |
| 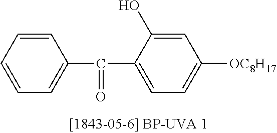 | Cyasorb UV 531 (American Cyanamid) Mark 1413 (Adeka Argus) Chimassorb 81 (Ciba-Geigy) UV-Chek AM 300 (Ferro) Hostavin ARO 8 (Hoechst) Rhodialux P (Rhòne- Poulenc) Uvasorb 3 C (Sigma) Seesorb 102 (Shipro Kasei) Aduvex 248 (Shell) Lowilite 22 (Chem. Werke Lowi) Sumisorb 130 (Sumitomo) Vioserb 130 (Kyodo Yakuhin) Uvinul 408 (BASF) |
| 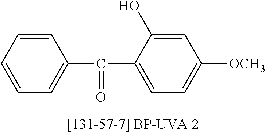 | Cyasorb UV 9 (American Cyanamid) Uvinul M-40 (BASF) UVA Bayer 325 (Bayer) Chimassorb 90 (Ciba-Geigy) Gafsorb 2 H 4M (GAF) Rhodialux A (Rhòne- Poulenc) Uvasorb MET (Sigma) Seesorb 101 (Shipro Kasei) Viosorb 110 (Kyodo Yakuhin) Sumisorb 110 (Sumitomo) |
| 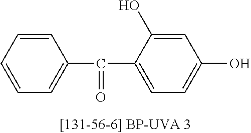 | Univul 400 (BASF) Aduvex 12 (Shell) Gafsorb 24 DH (GAF) DHB (Riedel de Haen) Rhodialux D (Rhòne- Poulenc) Seesorb 100 (Shipro Kasei) Viosorb 100 (Kyodo Yakuhin) |
| 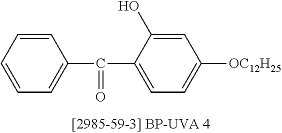 | Chimassorb 125 (Ciba- Geigy Eastman Inhibitor DOBP (Eastman Chem.) Gafsorb 2 H 4 DD (GAF) Rhodialux 1200 (Rhòne- Poulenc) Seesorb 103 (Shipro Kasai) |
| 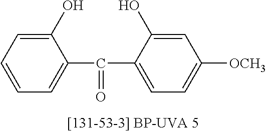 | Cyasorb UV 24 (American Cyanamid) Aduvex 24 (Shell) Sumisorb 140 (Sumitomo) |
| 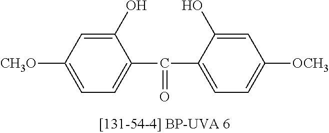 | Univul D-49 (BASF) Aduvex 424 (Shell) |
| 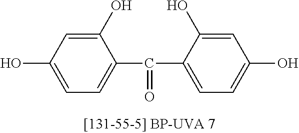 | Aduvex 412 (Shell) Uvirad D50 (BASF) |
| 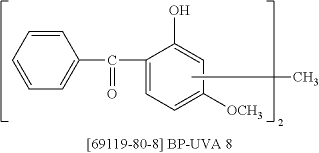 | Mark LA 51 (Adeka Argus) |
| 2-Hydroxyphenylbenzotriazoles | |
| 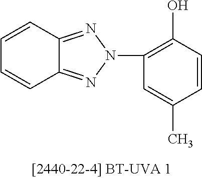 | Tinuvin P (Ciba-Geigy) Mark LA 32 (Adeka Argus) Uvasorb SV (Sigma) Seesorb 701 (Shipro Kasei) Lowilite 55 (Chem. Werke Lowi) Viosorb 520 (Kyodo Yakuhin) Sumisorb 200 (Sumitomo) |
| 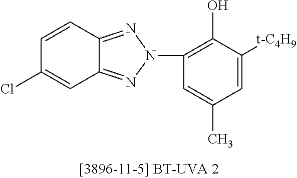 | Tinuvin 326 (Ciba-Geigy) Mark LA 36 (Adeka Argus) Seesorb 703 (Shipro Kasei) Viosorb 550 (Kyodo Yakuhin) Sumisorb 300 (Sumitomo) |
| 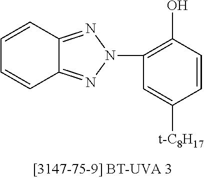 | Cyasorb UV 5411 (American Cyanamid) Sumisorb 340 (Sumitomo) Viosorb 583 (Kyodo Yakuhin) Seesorb 709 (Shipro Kasai) |
| 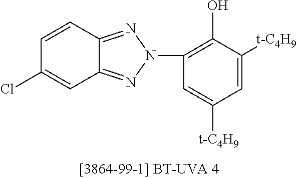 | Tinuvin 327 (Ciba-Geigy) Mark LA 34 (Adeka Argus) Seesorb 702 (Shipro Kasei) Viosorb 580 (Kyodo Yakuhin) |
| 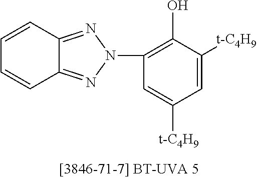 | Tinuvin 320 (Ciba-Geigy) Seesorb 705 (Shipro Kasei) Viosorb 582 (Kyodo Yakuhin) Sumisorb 320 (Sumitomo) |
| 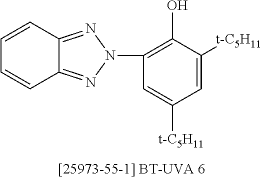 | Cyasorb 2337 (American Cyanamid) Tinuvin 328 (Ciba-Geigy) Seesorb 704 (Shipro Kasei) Viosorb 591 (Kyodo Yakuhin) Sumisorb 350 (Sumitomo) |
| 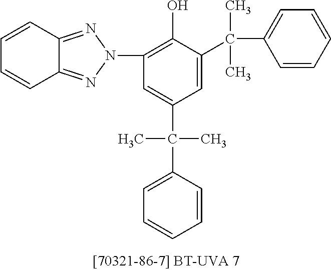 | Tinuvin 234 (Ciba-Geigy) Tinuvin 900 (Ciba-Geigy) |
| 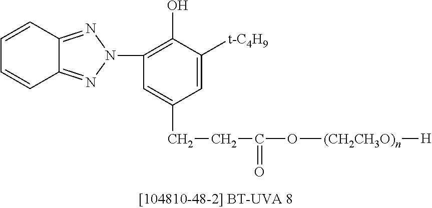 | Tinuvin 1130 (Ciba-Geigy) |
| 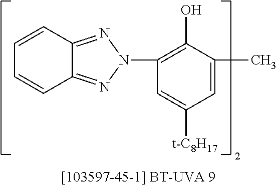 | Mark LA 31 (Adeka Argus) |
| 2-Hydroxyphenyltriazines | |
| 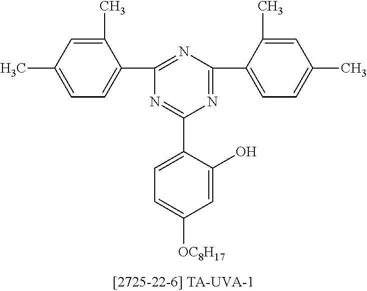 | Cyasorb 1164 (American Cyanamid) |
| Cinnamates | |
| 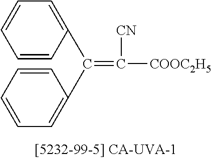 | Uvinul N -35 (BASF) Seesorb 501 (Shipro Kasei) Viosorb 910 (Kyodo Yakuhin) |
| 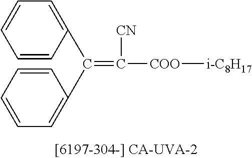 | Uvinul 539 (BASF) |
| Oxalanilides | |
| 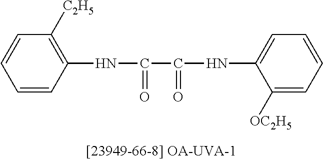 | Sanduvor VSU (Sandoz) Tinuvin 312 (Ciba-Geigy) |
| 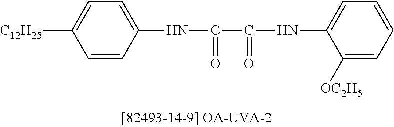 | Sanduvor 3206 (Sandoz) |
| Salicylates | |
| 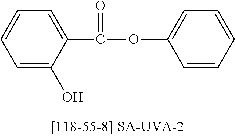 | Eastman Inhibitor OPS (Eastman Chem.) Seesorb 201 (Shipro Kasei) |
| 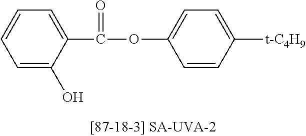 | Seesorb 202 (Shipro Kasei) Rhodialux K (Rhòne- Poulene) Viosorb 90 (Kyodo Yakuhin) |
| Formamidines | |
| 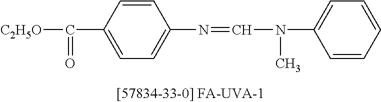 | Givsorb UV-1 (Givaudan) |
| 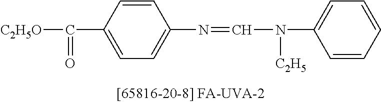 | Givsorb UV-2 (Givaudan) |
| 4-Hydroxybenzoates | |
| 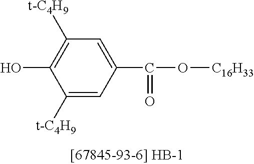 | Cyasorb UV 2908 (American Cyanamid) |
| 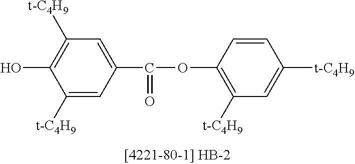 | Tinuvin 120 (Ciba- Geigy) Seesorb 712 (Shipro Kasei) UV-Chek AM 340 (Ferro) Viosorb 80 (Kyodo Yakuhin) Sumisorb 400 (Sumitomo) |
| Nickel complexes | |
| 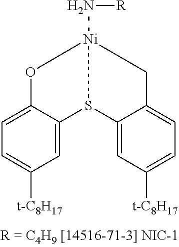 | Cyasorb UV 1084 (American Cyanamid) Chimassorb N 705 (Ciba-Geigy) Rhodialux Q 84 (Rhòne-Poulenc) Uvasorb Ni (Sigma) |
| same, | Seesorb 612 NH |
| R = C₈H₁₇ [67668-65-9] NIC-2 | (Shipro Kasei) |
| 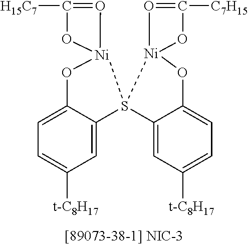 | UV-Chek AM 205 (Ferro) |
| 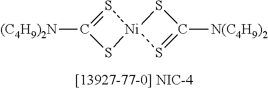 | UV-Chek AM 104 (Ferro) Antigene NBC (Sumitomo) Vanox NBC (R. T. Vanderbilt) |
| 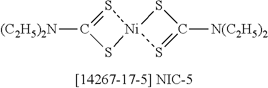 | Robac Ni PP (Robinson Brothers) |

Hindered amines and phosphorus compounds are preferably used as heat stabilizers.

Examples are

| | | | |
|---|---|---|---|
| 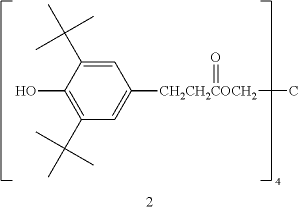 | tetrakis [methylene (3,5- di-tert-butyl-4- hydroxyhydro- cinnamate)] methane | [6683-19-8] | Irganox 101 |
| 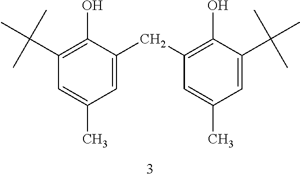 | 2,2′- methylenebis- (4- methyl-6-tert- butylphenol) | [119-47-1] | Cyanox 2246 |
| 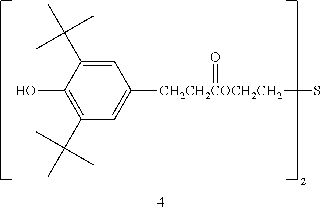 | | [41484-35-9] | Irganox 1035 |
| 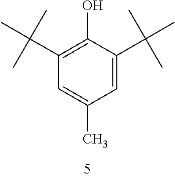 | 2,6-di- tert-butyl- 4- methylphenol | [128-37-0] | Butylated hydroxytolue (BHT) |
| 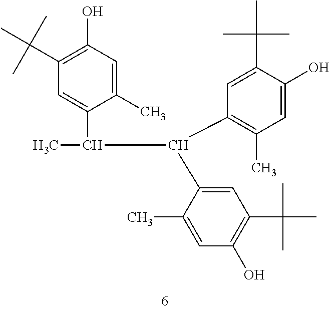 | | [1843-03-4] | Topanol CA |
| 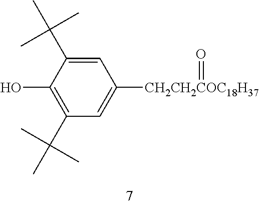 | | [2082-79-3] | Irganox 1076 |
| 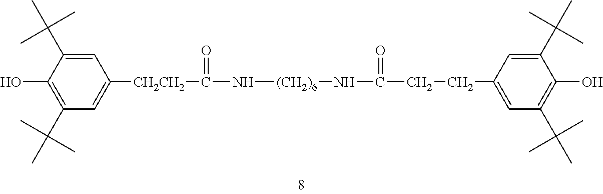 | N,N′- 1,6-hexa- methylene- bis-3- (3,5-di- tert-butyl- 4- hydroxy- phenyl) propionamide | [23128-74-7] | Irganox 1098 |
| 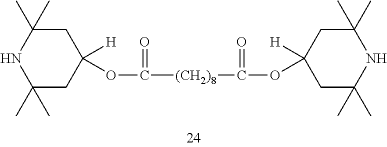 | | [52829-07-9] | Tinuvin 770 |
| 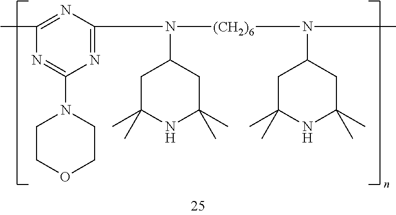 | | [82451-48-7] | Cyasorb UV-3346 |
| 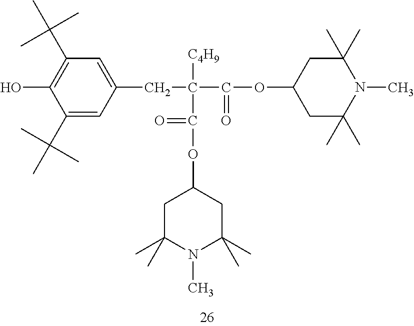 | | [63843-89-0] | Tinuvin 144 |
| 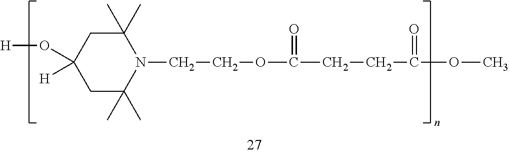 | | [65447-77-0] | Tinuvin 622LD |
| 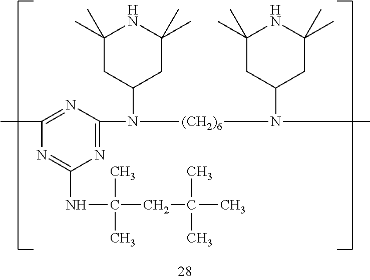 | | [70624-18-9] | Chimassorb 944LD |
| 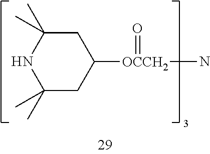 | | [64022-57-7] | Mark LA 55 |
| 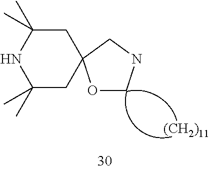 | | [84106-61-3] | Hostavin TMN 20 |
| 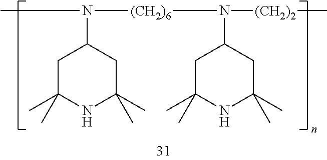 | | [61269-61-2] | Spinuvex A-36 |
| 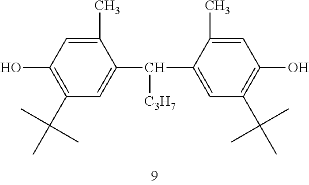 | 4,4′- Butylidenebis- (6- tert-butyl-3- methylphenol) | [85-60-9] | Santowhite powder |
| 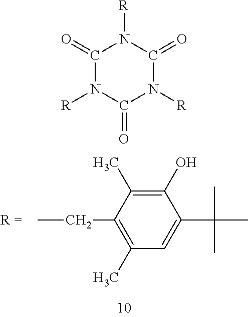 | | [40601-76-1] | Cyanox 1790 |
| 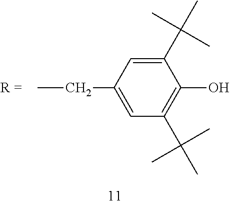 | | [27676-62-6] | Good-rite 3114 |
| 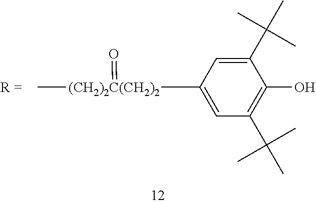 | | [34137-09-2] | Good-rite 3125 |
| 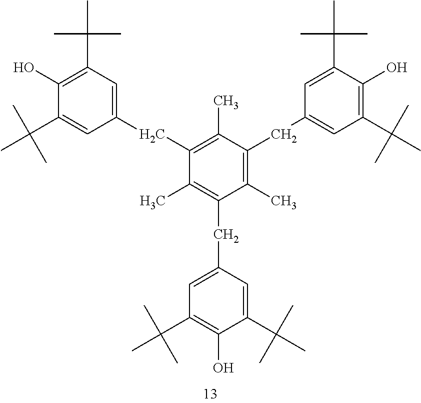 | | [1709-70-2] | Ethanox 330 Irganox 1330 |
| 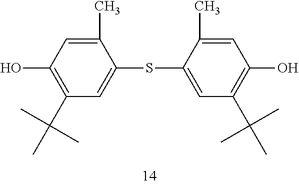 | 4,4′- Thiobis (2-tert- butyl-5- methylphenol) | [96-69-5] | Santonox R |
| 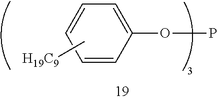 | | [26523-78-4] | TNPP |
| 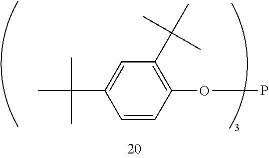 | | [31570-04-4] | Phosphite 168 |
| 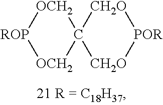 | | [3806-34-6] | Weston 618 |
| 22 R = 2,4-di-tert-butylphenyl | | [26741-53-7] | Ultranox 626 |
| 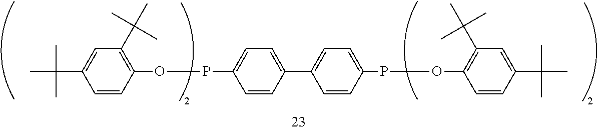 | | [38613-77-3] | Sandostab P-EPQ Irgafos P-EPQ |

A UV stabilizer is preferably also present. The UV stabilizer preferably comprises hindered amines, known as HALSs.

Examples are:

| | |
|---|---|
| Hindered amines | |
| 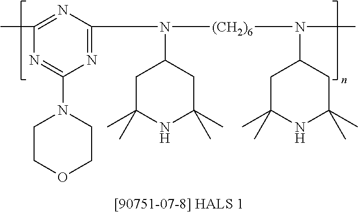 | Cyasorb UV 3346 (American Cyanan |
| 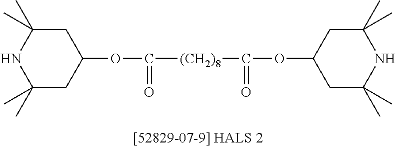 | Tinuvin 770 (Ciba-Geigy) Mark LA 77 (Adeka Argus) Sanol LK 770 (Sankyo) Lowilite 77 (Chem. Werke Lowi) |
| 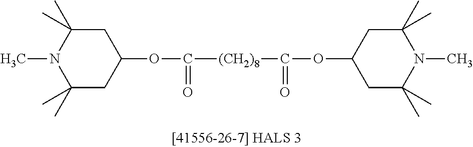 | Tinuvin 765 (Ciba-Geigy) Tinuvin 292 (Ciba-Geigy) Sanol 292 (Sankyo) |
| 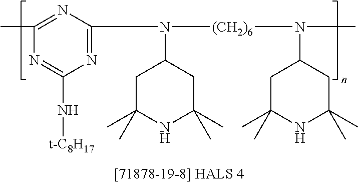 | Chimassorb 944 (Ciba-Geigy) |
| 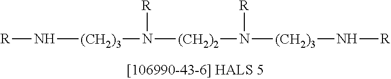 | Chimassorb 119 (Ciba-Geigy) |
| 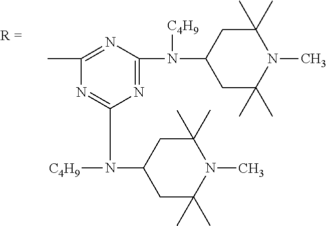 | |
| 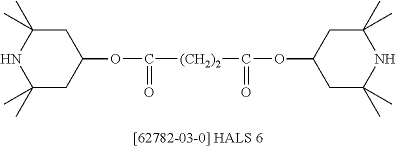 | Tinuvin 780 (Ciba-Geigy) |
| 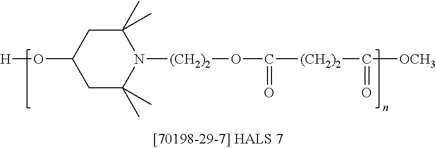 | Tinuvin 622 (Ciba-Geigy) |
| 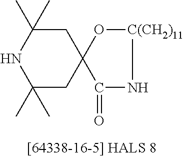 | Hostavin N-20 (Hoechst) |
| 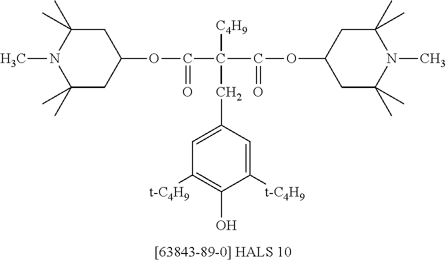 | Tinuvin 144 (Ciba-Geigy) |
| 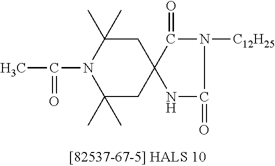 | Tinuvin 440 (Ciba-Geigy) |
| 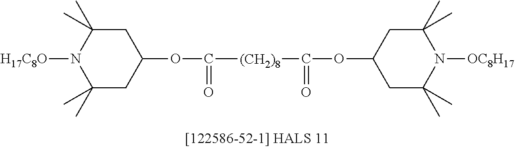 | Tinuvin 123 (Ciba-Geigy) |
| 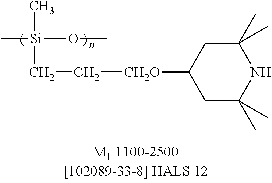 | Uvasil 299 (Enichem) |
| 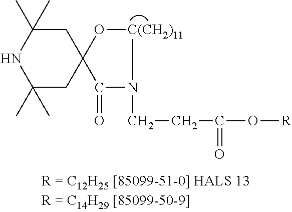 | Sanduvor 3050 (Sandoz) |
| 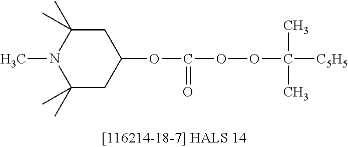 | Lupersol HA 505 (Atochem) |
| 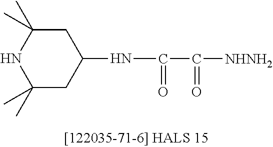 | Lupersol HA-R (Atochem) |
| 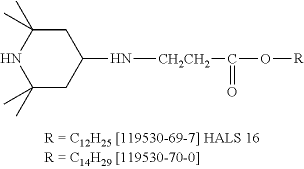 | Sanduvor 3052 (Sandoz) |
| 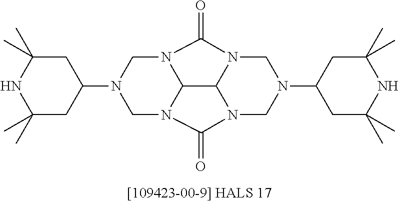 | Uvinul 4049 H (BASF) |
| 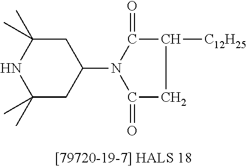 | Cyasorb UV 3581 (American Cyanamid) Sanduvor 3055 (Sandoz) |
| 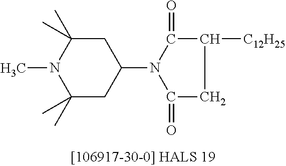 | Cyasorb UV 3604 (American Cyanamid) Sanduvor 3056 (Sandoz) |
| 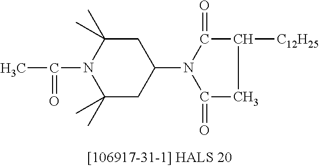 | Cyasorb UV 3668 (American Cyanamid) Sanduvor 3058 (Sandoz) |

Preference is given to using a combination of UV absorber and light stabilizer which are liquid at temperatures below 50° C., if appropriate alone or together with further stabilizers. This can also be achieved by formation of a joint eutectic mixture.

Particular preference is given to the UV absorber being present in a higher concentration than the light stabilizer in the system. The UV absorber is very particularly preferably used in at least twice the concentration of the light stabilizer.

The concentration of free amino groups or isocyanate groups in the polymer (I) is preferably less than 40 mmol/kg, particularly preferably less than 15 mmol/kg and very particularly preferably less than 10 mmol/kg.

This is necessary because, in particular, it has surprisingly been found that this composition is transparent and colorless even after weathering in the open. The degree of yellowing can be indicated by reporting of a delta Y or Yellowness value.

The delta Y after storage for 1000 hours in a controlled-atmosphere cabinet at 85° C. and 85% rel. atmospheric humidity is preferably less than 10, particularly preferably less than 5.

The Yellowness Index is determined in accordance with ASTM E313.

The polydiorganosiloxane-urea copolymer of the general formula (1) displays high molecular weights and good mechanical properties combined with good processing properties. The processing properties are, inter alia, defined by the MVR, which is determined in accordance with DIN EN 1133. This value indicates the volume of a polymer which is pressed through a die within 10 minutes under a given weight and at a given temperature. This value indicates the flowability of a polymer under defined conditions.

The composition of the invention preferably has an MVR in the range from 1 to 400 ml/10 min (measured at 180° C., 21.6 kg loading weight), particularly preferably an MVR in the range from 5 to 200 ml/10 min (measured at 180° C., 21.6 kg loading weight), very particularly preferably an MVR in the range from 15 to 120 ml/10 min (measured at 180° C., 21.6 kg loading weight).

A significant improvement in the mechanical properties can be achieved by, in particular, the use of chain extenders such as dihydroxy compounds or water in addition to the urea groups. This makes it possible to obtain materials which are quite comparable in terms of the mechanical properties to conventional silicone rubbers but have an increased transparency and into which no additional active filler has to be incorporated.

The chain extenders used preferably have the general formula (6)

HZ-D-ZH,

where D and Z are as defined above. If Z is O, the chain extender of the general formula (6) can also be reacted with diisocyanate of the general formula

OCN—Y—NCO

(5) in a separate step before the reaction.

Preference is given to at least 50 mol %, in particular at least 75 mol %, of urea groups, based on the sum of urethane and urea groups, being present in the copolymer of the general formula (1).

Preference is given to at least 50% by weight, in particular at least 75% by weight, of polydiorganosiloxanes, based on the sum of the urethane and urea groups, being present in the copolymer of the general formula (1).

The functional polydialkylsiloxanes used for preparing the compounds of the invention can be prepared according to the prior art, with particular value being attached to a targeted preparation of bifunctional compounds as described, for example, in EP 250248 or in DE 10137855.

Examples of diisocyanates of the general formula (5) to be used are aliphatic compounds such as isophorone diisocyanate, hexamethylene 1,6-diisocyanate, tetramethylene 1,4-diisocyanate and methylene-dicyclohexyl 4,4′-diisocyanate or aromatic compounds such as methylenediphenyl 4,4′-diisocyanate, tolylene 2,4-diisocyanate, tolylene 2,5-diisocyanate, tolylene 2,6-diisocyanate, m-phenylene diisocyanate, p-phenylene diisocyanate, m-xylylene diisocyanate, tetramethyl-m-xylylene diisocyanate or mixtures of these isocyanates. An example of commercially available compounds are the diisocyanates of the DESMODUR® series (H,I,M,T,W) from Bayer AG, Germany. Preference is given to aliphatic diisocyanates in which Y is an alkylene radical, since these lead to materials which display improved UV stabilities, which is advantageous in the case of exterior use of the polymers.

The α,ω-OH-terminated alkylenes of the general formula (6) are preferably polyalkylenes or polyoxyalkylenes. These are preferably largely free of contamination by monofunctional, trifunctional or higher-functional polyoxyalkylenes. Here, it is possible to use polyether polyols, polytetramethylene diols, polyester polyols, polycaprolactonediols or even α,ω-OH-terminated polyalkylenes based on polyvinyl acetate, polyvinyl acetate-ethylene copolymers, polyvinyl chloride copolymers, polyisobutanediols. Preference is given to using polyoxyalkylenes, particularly preferably polypropylene glycols. Such compounds are commercially available with molecular masses Mn up to more than 10 000 as raw materials for, inter alia, flexible polyurethane foams and for coating applications. Examples are the BAYCOLL® polyether polyols and polyester polyols from Bayer AG, Germany, or the Acclaim® polyether polyols from Lyondell Inc., USA. It is also possible to use monomeric α,ω-alkylenediols such as ethylene glycol, propanediol, butanediol or hexanediol. Furthermore, dihydroxy compounds likewise include, for the purposes of the invention, bishydroxyalkylsilicones as are marketed by, for example, Goldschmidt under the name Tegomer H—Si 2111, 2311 and 2711.

To avoid unstable end groups, monoisocyanate compounds or monoamine compounds such as dodecylamine or preferably monofunctional polydiorganosiloxanes may optionally be added as additional additives, with this monofunctional siloxane component preferably being added to produce defined contents so as to ensure control of the rheological properties of the composition.

It is likewise possible to use relatively unreactive components, e.g. carbinol-functional compounds, which owing to their relative inertness react last and thus form the end group of the polymers.

The invention further provides a process for producing polymers from a composition according to the invention, wherein the polymer is firstly pelletized and is then melted for further processing, with the UV absorber and if appropriate the UV stabilizer being mixed in.

The invention further provides a process for producing polymers from a composition according to the invention, wherein the UV absorber and if appropriate the UV stabilizer are added to the polymer during its production.

The preparation of the above-described copolymers of the general formula (1) can be carried out either in solution or in the solid state, continuously or discontinuously. The important thing is that optimal and homogeneous mixing of the constituents of the selected polymer mixture occurs under the reaction conditions and phase incompatibility is prevented if necessary by means of solubilizers. The preparation depends on the solvent used. If the proportion of hard segments such as urethane or urea units is large, a solvent having a high solubility parameter, for example dimethylacetamide, may have to be chosen. THF has been found to be sufficiently well suited for most syntheses. Preference is given to dissolving all constituents in an inert solvent. Particular preference is given to a synthesis without solvent.

For the reaction without solvent, homogenization of the mixture is of critical importance in the reaction. Furthermore, the polymerization can also be controlled by the choice of the reaction sequence in a stepwise synthesis.

The preparation should, in the interests of better reproducibility, generally be carried out with exclusion of moisture and under protective gas, usually nitrogen or argon.

The reaction is preferably carried out, as is customary in the preparation of polyurethanes, by addition of a catalyst. Suitable catalysts for the preparation are dialkyltin compounds such as dibutyltin dilaurate, dibutyltin diacetate or tertiary amines such as N,N-dimethylcyclohexylamine, 2-dimethylaminoethanol, 4-dimethylaminopyridine.

The mixtures of the invention can be obtained in a number of ways.

One possibility is mixing the stabilizers according to the invention into the already fully polymerized organopolysiloxane-polyurea-polyurethane block copolymer. In this case, the polymer can be present either as solid or granules or as a polymer melt. This mixture can be homogenized by reheating, e.g. in a heated kneader.

A further, preferred possibility is addition of the stabilizers according to the invention to one of the starting materials used for preparing the organopolysiloxane-polyurea-polyurethane block copolymers. Here, the stabilizers are particularly preferably added to the silicone component.

The subsequent polymerization then results in the stabilizers being homogeneously distributed in the end product.

The invention further provides sheets, films or shaped bodies comprising polymers according to the invention.

The invention further provides a process for the encapsulation of solar cells, wherein polymers according to the invention are used.

Materials used, which are also generally preferred in the context of the general description are:

bis(aminopropyl)-terminated polydimethylsiloxane, molecular weight (Mn)=2900 g/mol, FLUID NH 40 D, Wacker Chemie AG

mono(aminopropyl)-functional polydimethylsiloxane, molecular weight (Mn)=980 g/mol, SLM 446011-15, Wacker Chemie AG

(methylenebis(4-isocyanatocyclohexane)), Desmodur W, Bayer AG benzene, 1,3-bis(1-isocyanato-1-methylethyl), m-TMXDI, Cytec

Tinuvin P: phenol, 2-(2H-benzotriazol-2-yl)-4-methyl, Ciba SC, solid

Tinuvin 571: phenol, 2-(2H-benzotriazol-2-yl)-4-methyl-6-dodecyl, Ciba SC, liquid

Tinuvin 765: bis(1,2,2,6,6-pentamethyl-4-piperidyl) sebacate, Ciba SC, liquid

Irganox 1135: 3,5-di-tert-butyl-4-hydroxyhydrocinnamic acid, C7-9-branched alkylester, Ciba SC, liquid stabilizer mixture B75 (mixture of Irganox 1135, Tinuvin 571, Tinuvin 765) Ciba SC., liquid

Irradiations were generally carried out in a Suntester CPS+ from Atlas at a power of 750 W/m² and a temperature of 55° C. (black standard temperature).

Determinations of the MVR were generally carried out at 180° C. under a loading weight of 21.6 kg in accordance with DIN EN 1133.

### EXAMPLE 1

In a twin-screw kneader from Collin, Ebersberg, having 6 heating zones, the diisocyanate was metered under a nitrogen atmosphere into the first heating zone and the aminopropyl-terminated silicone oil was metered into the second heating zone. The temperature profile of the heating zones was programmed as follows: zone 1 30° C., zone 2 140° C., zone 3 160° C., zone 4 185° C., zone 5 185° C., zone 6 180° C. The rotational speed was 150 rpm. The diisocyanate (methylenebis(4-isocyanatocyclohexane)) was metered into zone 1 at 1320 mg/min and the amino oil (2900 g/mol) was metered into zone 2 at 15 g/min. A polydimethylsiloxane-polyurea block copolymer having a molecular weight of 84 200 g/mol and an MVR (21.6 kg, 180° C.) of 63 could be obtained at the die of the extruder, and this was subsequently pelletized.

### EXAMPLE 2

In a twin-screw kneader from Collin, Ebersberg, having 6 heating zones, the diisocyanate was metered under a nitrogen atmosphere into the first heating zone and the aminopropyl-terminated (2900 g/mol, FLUID NH 40 D) silicone oil was metered into the second heating zone. The temperature profile of the heating zones was programmed as follows: zone 1 30° C., zone 2 140° C., zone 3 170° C., zone 4 180° C., zone 5 175° C., zone 6 170° C. The rotational speed was 150 rpm. The diisocyanate (TMXDI from Cytec) was metered into zone 1 at 1230 mg/min and the amino oil (2900 g/mol) was metered into zone 2 at 15 g/min. A polydimethylsiloxane-polyurea block copolymer having a molecular weight of 96 200 g/mol could be obtained at the die of the extruder, and this was subsequently pelletized.

### EXAMPLE 3

### Production by Blending Process

The polymer from example 2 was admixed with various amounts of the stabilizer mixture B75 from Ciba SC (100 ppm, 250 ppm, 500 ppm) and subsequently compounded in a 2-screw kneader. The homogeneous mixture obtained in this way was, after cooling and pelletization, irradiated in a Suntester from Atlas (750 W/m²). Samples were taken after various times and their molecular weight (weight average) was determined.

| Polymer | Addition | Mw/0 h | Mw/24 h | Mw/48 h | Mw/72 h |
|---|---|---|---|---|---|
| Example 2 | 0 ppm | 90 700 | 42 500 | 26 700 | 24 200 |
| Example 2 | 100 ppm | 87 900 | 83 500 | 84 800 | 87 500 |
| Example 2 | 250 ppm | 88 600 | 82 500 | 86 500 | 89 200 |
| Example 2 | 500 ppm | 86 400 | 89 500 | 92 000 | 89 100 |

The optical properties of the material were likewise determined:

| Polymer | Addition | 0 h | 24 h | 48 h | 72 h |
|---|---|---|---|---|---|
| Example 2 | 0 ppm | elastic, | elastic, opaque | elastic, cloudy | brittle, cloudy |
| | | transparent | | | |
| Example 2 | 100 ppm | elastic, | elastic, | elastic, | elastic, |
| | | transparent | transparent | transparent | transparent |
| Example 2 | 250 ppm | elastic, | elastic, | elastic, | elastic, |
| | | transparent | transparent | transparent | transparent |
| Example 2 | 500 ppm | elastic, | elastic, | elastic, | elastic, |
| | | transparent | transparent | transparent | transparent |

It can clearly be seen that materials which are significantly more UV-stable can be obtained using the selected stabilizer concentration and stabilizer combination.

### EXAMPLE 4

The polymer from example 1 was admixed in a bucket with various amounts of the stabilizer mixture B75 from Ciba SC (1000 ppm, 2500 ppm, 5000 ppm) and subsequently compounded in a 2-screw kneader. The homogeneous mixture obtained in this way was, after cooling and pelletization, irradiated in a Suntester from Atlas (750 W/m²). After 1000 hours, samples were taken and their molecular weight (weight average) was determined.

| Polymer | Addition | Mw/0 h | Mw/1000 h |
|---|---|---|---|
| Example 1 | 0 ppm | 87 900 | 22 500 |
| Example 1 | 1000 ppm | 87 200 | 86 900 |
| Example 1 | 2500 ppm | 88 600 | 88 600 |
| Example 1 | 5000 ppm | 86 400 | 87 500 |

The optical and mechanical properties of the material were likewise determined:

| Polymer | Addition | 0 h | 1000 h |
|---|---|---|---|
| Example 1 | 0 ppm | elastic, | brittle, |
| | | transparent | transparent |
| Example 1 | 1000 ppm | elastic, | elastic, |
| | | transparent | transparent |
| Example 1 | 2500 ppm | elastic, | elastic, |
| | | transparent | transparent |
| Example 1 | 5000 ppm | elastic, | elastic, |
| | | transparent | transparent |

It can clearly be seen that materials which are more highly UV-stable can be obtained using the selected stabilizer concentration and stabilizer combination.

### EXAMPLE 5

In a twin-screw kneader from Collin, Ebersberg, having 6 heating zones, the diisocyanate was metered under a nitrogen atmosphere into the first heating zone and the aminopropyl-terminated (FLUID NH 40 D) silicone oil was metered into the second heating zone. 1000 ppm of Tinuvin B75 was mixed into the silicone oil before introduction. The temperature profile of the heating zones was programmed as follows: zone 1 30° C., zone 2 140° C., zone 3 160° C., zone 4 185° C., zone 5 185° C., zone 6 180° C. The rotational speed was 150 rpm. The diisocyanate (methylenebis(4-isocyantocyclohexane)) was metered into zone 1 at 1320 mg/min and the amino oil (FLUID NH 40 D, 2900 g/mol) was metered into zone 2 at 15 g/min. A polydimethylsiloxane-polyurea block copolymer having a molecular weight of 88 300 g/mol and an MVR (21.6 kg, 180° C.) of 57 could be obtained at the die of the extruder and this was subsequently pelletized.

### EXAMPLE 6

The polymer from example 5 was irradiated in a Suntester from Atlas (750 W/m²). After 1000 hours, samples were taken and their molecular weight (weight average) was determined.

| Polymer | Addition | Mw/0 h | Mw/1000 h |
|---|---|---|---|
| Example 5 | 1000 ppm | 88 300 g/mol | 84 300 |

The optical and mechanical properties of the material were likewise determined:

| Polymer | Addition | 0 h | 1000 h |
|---|---|---|---|
| Example 1 | 1000 ppm | elastic, | elastic, |
| | | transparent | transparent |

It can clearly be seen that materials which are more highly UV-stable can be obtained using the selected stabilizer concentration and stabilizer combination when a stabilizer is added to a starting material of the polyaddition.

### EXAMPLE 7

In a twin-screw kneader from Collin, Ebersberg, having 6 heating zones, the diisocyanate was metered under a nitrogen atmosphere into the first heating zone and the aminopropyl-terminated silicone oil (FLUID NH 40 D) was metered into the second heating zone. The temperature profile of the heating zones was programmed as follows: zone 1 30° C., zone 2 140° C., zone 3 160° C., zone 4 185° C., zone 5 185° C., zone 6 180° C. The rotational speed was 150 rpm. The diisocyanate (methylenebis(4-isocyantocyclohexane)) was metered into zone 1 at 1320 mg/min and the amino oil (Fluid NH 40 D, 2900 g/mol) was metered into zone 2 at 15.2 g/min. A polydimethylsiloxane-polyurea block copolymer having a molecular weight of 65 200 g/mol and an MVR (21.6 kg, 180° C.) of 88 could be obtained at the die of the extruder and this was subsequently pelletized.

### EXAMPLE 8

The polymer from example 8 was admixed in a bucket with various amounts of the stabilizer mixture Tinuvin 571 (UV absorber) and Tinuvin 765 (UV stabilizer) from Ciba SC and subsequently compounded in a 2-screw kneader. The homogeneous mixture obtained in this way was, after cooling and pelletization, irradiated in a Suntester from Atlas (750 W/m²). After 200 hours, samples were taken and their molecular weight (weight average) was determined.

| | Addition | Addition | | |
|---|---|---|---|---|
| | of | of | | |
| | Tinuvin | Tinuvin | | |
| Polymer | 571 | 765 | Mw/0 h | Mw/200 h |
| Example 8 | 0 ppm | 0 ppm | 65 200 g/mol | 20 600 |
| Example 8 | 200 ppm | 0 ppm | 65 200 g/mol | 44 400 |
| Example 8 | 0 ppm | 200 ppm | 65 200 g/mol | 34 900 |
| Example 8 | 200 ppm | 200 ppm | 65 200 g/mol | 55 200 |
| Example 8 | 200 ppm | 100 ppm | 65 200 g/mol | 59 300 |
| Example 8 | 200 ppm | 50 ppm | 65 200 g/mol | 64 800 |

It can be seen that a combination of UV stabilizer and UV absorber represents the best UV protection; the UV absorber should be used in a higher concentration than the UV stabilizer.

### EXAMPLE 9

In a twin-screw kneader from Collin, Ebersberg, having 6 heating zones, the diisocyanate was metered under a nitrogen atmosphere into the first heating zone and the aminopropyl-terminated (Fluid NH 40 D) silicone oil (bisaminopropyl-terminated PDMS having a molecular weight of 2900 g/mol; BAPS) was metered into the second heating zone. Various amounts of stabilizer Tinuvin 571, Tinuvin 765 and Irganox 1135 and if appropriate a monofunctional aminopropyl-terminated PDMS (MAPS) having a molecular weight of 980 g/mol were mixed into the aminopropyl-terminated silicone oil (FLUID NH 40 D). The temperature profile of the heating zones was programmed as follows: zone 1 30° C., zone 2 140° C., zone 3 160° C., zone 4 185° C., zone 5 185° C., zone 6 180° C. The rotational speed was 150 rpm. The diisocyanate (methylenebis(4-isocyantocyclohexane)) (H12MDI) was metered into zone 1 at 1320 mg/min and the amino oil component was metered into zone 2 at 15 g/min. A polydimethylsiloxane-polyurea block copolymer could in each case be obtained at the die of the extruder and this was subsequently pelletized. All materials were colorless, highly transparent polymers.

| | | Composition of amino oil component | | | | |
|---|---|---|---|---|---|---|
| | | | | Tinuvin | Tinuvin | Irganox |
| Experiment | Isocyanate | BAPS | MAPS | 571 | 765 | 1135 |
| 1 | H12MDI | 100% | 0% | 0% | 0% | 0% |
| 2 | H12MDI | 99.83% | 0% | 0.1% | 0.03% | 0.04% |
| 3 | H12MDI | 99.75% | 0% | 0.1% | 0.1% | 0.05% |
| 4 | H12MDI | 98% | 2% | 0% | 0% | 0% |
| 5 | H12MDI | 97.83% | 2% | 0.1% | 0.03% | 0.04% |
| 6 | H12MDI | 97.75% | 2% | 0.1% | 0.1% | 0.05% |
| 7 | H12MDI | 97.95% | 2% | 0% | 0% | 0.05% |

The individual polymers were subjected to a molecular weight determination, the content of free amino groups was determined by NMR and the polymers were then in each case stored at 85° C. and 85% relative atmospheric humidity in a controlled-atmosphere chamber for 6 weeks.

| | Before weathering | | | | | |
|---|---|---|---|---|---|---|
| | MVR | | | After weathering | | |
| | (180° C., | Molecular | Amine | Molecular | | |
| Experiment | 21.6 kg) | weight | content | weight | Transparency | Appearance |
| 1 | 48 | 121 300 | 43 mmol/kg | 95 200 | >92% | yellowed |
| 2 | 48 | 123 380 | 42 mmol/kg | 84 800 | >92% | yellowed |
| 3 | 48 | 125 700 | 41 mmol/kg | 83 600 | >92% | yellowed |
| 4 | 57 | 87 500 | 5 mmol/kg | 84 600 | >92% | slightly |
| | | | | | | yellowed |
| 5 | 58 | 80 300 | 5 mmol/kg | 83 200 | >92% | colorless |
| 6 | 58 | 84 900 | 4 mmol/kg | 84 500 | >92% | colorless |
| 7 | 58 | 83 800 | 5 mmol/kg | 84 200 | >92% | colorless |

It can be seen how the addition of monofunctional silicone oils sets a lower limit to the molecular weight. Yellowing caused by weathering can effectively be achieved by reducing the content of free amines. At the same time, it has surprisingly been found that a reduction in the content of free amines can limit the molecular weight degradation during weathering.

### EXAMPLE 10

### Production by Blending Process

The polymer from example 2 was admixed with various amounts of the solid Tinuvin P from Ciba SC (100 ppm, 250 ppm, 500 ppm) and subsequently compounded in a 2-screw kneader.

The optical properties of the material were determined:

| Polymer | Addition | 0 h |
|---|---|---|
| Example 2 | 0 ppm | elastic, |
| | | transparent |
| Example 2 | 100 ppm | elastic, cloudy |
| Example 2 | 250 ppm | elastic, |
| | | nontransparent |
| Example 2 | 500 ppm | elastic, |
| | | nontransparent |

It can clearly be seen that no transparent materials can be obtained using the selected incompatible stabilizer solid.

1.-10. (canceled)

11. A composition comprising from 50 to 99.999% of an organopolysiloxane-polyurea-polyurethane block copolymer of the formula (1) 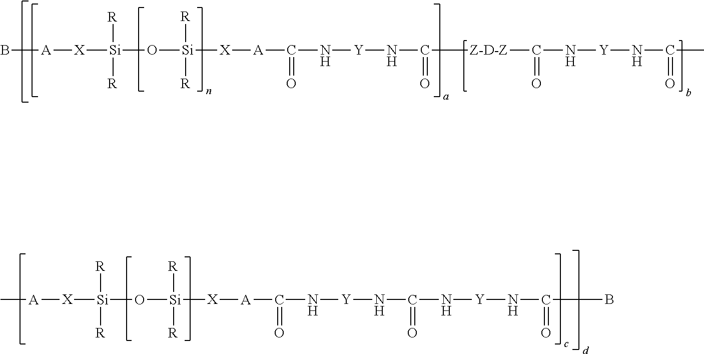
and containing from 0.001% to 10% of at least one UV absorber compatible with the polymer of the general formula I, the percents by weight being relative to the total weight of the composition, with the concentration of free amino groups or isocyanate groups in the polymer (I) being less than 40 mmol/kg,
where
R is a monovalent hydrocarbon radical having from 1 to 20 carbon atoms, optionally substituted by fluorine or chlorine,
X is an alkylene radical having from 1 to 20 carbon atoms, in which nonadjacent methylene units are optionally replaced by —O— groups,
A is an oxygen atom or an amino group —NR′—,
Z is an oxygen atom or an amino group —NR′—,
R′ is hydrogen or an alkyl radical having from 1 to 10 carbon atoms,
Y is a divalent hydrocarbon radical which has from 1 to 20 carbon atoms and is optionally substituted by fluorine or chlorine,
D is an alkylene radical which has from 1 to 700 carbon atoms and is optionally substituted by fluorine, chlorine, C₁-C₆-alkyl or C₁-C₆-alkyl ester and in which nonadjacent methylene units are optionally replaced by —O—, —COO—, —OCO— or —OCOO— groups,
B is hydrogen or a functional or nonfunctional organic or organosilicon radical,
n is from 1 to 1000,
a is at least 1,
b is from 0 to 40,
c is from 0 to 30, and
d is greater than 0.

12. The composition of claim 11, wherein the UV absorber comprises a benzotriazole or triazine.

13. The composition of claim 11, wherein a UV stabilizer is additionally present.

14. The composition of claim 12, wherein a UV stabilizer is additionally present.

15. The composition of claim 13, wherein the UV stabilizer comprises a hindered amine light stabilizer (HALS).

16. The composition of claim 11, wherein amino groups are present, in a concentration of less than 40 mmol/kg.

17. A process for producing a polymer composition of claim 11, comprising firstly pelletizing a block copolymer of the formula (1), melting the pelletized copolymer, and mixing in the UV absorber and optionally a UV stabilizer.

18. A process for producing a composition of claim 11, comprising adding the UV absorber and optionally a UV stabilizer during production of the copolymer.

19. The composition of claim 11, which is in the form of a sheet, film or shaped body.

20. A process for the encapsulation of solar cells, comprising encapsulating a solar cell with a composition of claim 11.

21. The composition of claim 11, which comprises from 50 to 99.999% of an organopolysiloxane-polyurea-polyurethane block copolymer of the formula (1) 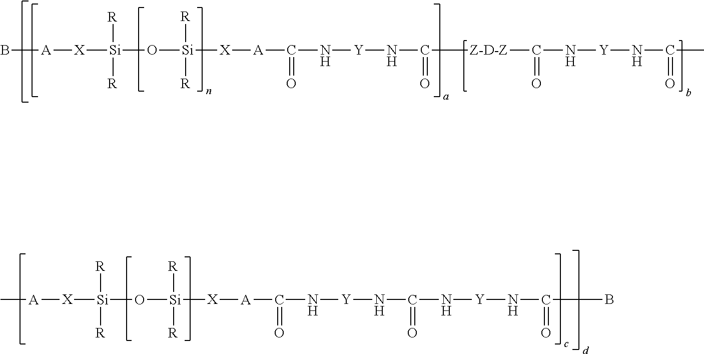
characterized in that the concentration of free amino groups or isocyanate groups in the polymer (I) is less than 40 mmol/kg and no UV absorber is present,
where
R is a monovalent hydrocarbon radical having from 1 to 20 carbon atoms, optionally substituted by fluorine or chlorine,
X is an alkylene radical having from 1 to 20 carbon atoms, in which nonadjacent methylene units are optionally replaced by —O— groups,
A is an oxygen atom or an amino group —NR′—,
Z is an oxygen atom or an amino group —NR′—,
R′ is hydrogen or an alkyl radical having from 1 to 10 carbon atoms,
Y is a divalent hydrocarbon radical which has from 1 to 20 carbon atoms and is optionally substituted by fluorine or chlorine,
D is an alkylene radical which has from 1 to 700 carbon atoms and is optionally substituted by fluorine, chlorine, C₁-C₆-alkyl or C₁-C₆-alkyl ester and in which nonadjacent methylene units are optionally replaced by —O—, —COO—, —OCO— or —OCOO— groups,
B is hydrogen or a functional or nonfunctional organic or organosilicon radical,
n is from 1 to 1000,
a is at least 1,
b is from 0 to 40,
c is from 0 to 30, and
d is greater than 0.
